(19) United States
(12) Patent Application Publication
(10) Pub. No.: US 2026/0009118 A1
(43) Pub. Date: Jan. 8, 2026

(54) SELECTIVE ETCHING OF SILICON NITRIDE DIELECTRICS WITH MICROWAVE OXIDATION

(71) Applicant: Applied Materials, Inc., Santa Clara, CA (US)

(72) Inventors: Liang SONG, San Jose, CA (US); Chengyu LIU, Santa Clara, CA (US); Sundarapandian Ramalinga Vijayalakshmi REDDY, Bangalore (IN); Avinash NAYAK, Bangalore (IN); Weiling DONG, Santa Clara, CA (US); Annie CHANG, Arcadia, CA (US); Sireesh ADIMADHYAM, Santa Clara, CA (US); Irena WYSOK, San Jose, CA (US)

(21) Appl. No.: 19/257,785

(22) Filed: Jul. 2, 2025

(30) Foreign Application Priority Data
Jul. 8, 2024 (IN) 202441052010

(51) Int. Cl. C23C 14/00; C23C 14/06; C23C 14/34; C23C 14/54; C23C 14/58

(52) U.S. Cl. CPC C23C 14/0036; C23C 14/0617; C23C 14/3485; C23C 14/541; C23C 14/5806

(57) ABSTRACT

A method for depositing a layer on a substrate includes flowing a process gas that comprises a sputtering working gas and a reactive gas to a processing region of a physical vapor deposition chamber. The sputtering working gas comprises an inert gas and the reactive gas comprises nitrogen. The method further includes biasing a target disposed in a processing chamber, wherein the biasing of the target comprises providing a direct current (DC) power of at least 30 kilowatts (kW) to the target while the process gas is flowing, and heating the substrate disposed within the processing region to a temperature between about 200° C. and about 400° C. while flowing the process gas and biasing the target.

### CROSS-REFERENCE TO RELATED APPLICATIONS

This application claims the benefit of Indian Provisional Patent Application Serial No. 202441052010 filed Jul. 8, 2024, which is hereby incorporated by reference.

### BACKGROUND

### Field

Embodiments of the present disclosure generally relate to methods for depositing aluminum nitride films via a physical vapor deposition process.

### Description of the Related Art

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased. Such geometry reduction has driven innovation into various deposition processes to assist in the production of these complex devices.

High conductivity dielectric films used in backside power delivery network (BSPDN) and inter-metal dielectric (IMD) applications has received a lot of interest in recent years. Advantages to using these types of films in BSPDN applications include the ability to separate signal and power delivery networks, increased chip utilization, and reduced fine metal pitch complexity for enhanced device and/or system performance. Thermal interlayer materials with a high thermal conductivity (kappa) for device and carrier wafer bonding is needed to achieve the desired structure for the BSPDN applications.

Applications that require the use of inter-metal dielectric (IMD) layers require enhanced electrical properties, which include a low leakage current and a low dielectric constant.

Thus, there is a need to develop a new high conductivity dielectric film deposition process, such as an aluminum nitride (AlN) layer deposition process, that solves the problems described above.

### SUMMARY

According to one or more embodiments, a method for depositing a layer on a substrate includes flowing a process gas that comprises a sputtering working gas and a reactive gas to a processing region of a physical vapor deposition chamber, wherein the sputtering working gas comprises an inert gas and the reactive gas comprises nitrogen, biasing a target disposed in a processing chamber, wherein the biasing of the target comprises providing a direct current (DC) power of at least 30 kilowatts (kW) to the target while the process gas is flowing, wherein the target comprises aluminum (Al), and heating the substrate disposed within the processing region to a temperature between about 200° C. and about 400° C. while flowing the process gas and biasing the target.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic top view of a multi-chamber processing system, according to embodiments described herein.

FIG. 2 is a schematic of a physical vapor deposition (PVD) processing chamber, according to embodiments described herein.

FIG. 3 is a process flow diagram of a method of processing a substrate, according to embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

Embodiments herein generally relate to a method and apparatus for forming a high conductivity dielectric film, such as an aluminum nitride (AlN) layer or aluminum oxynitride (AlON) layer, for use in various applications that can include, but are not limited to semiconductor device and packaging applications.

### Processing System Example

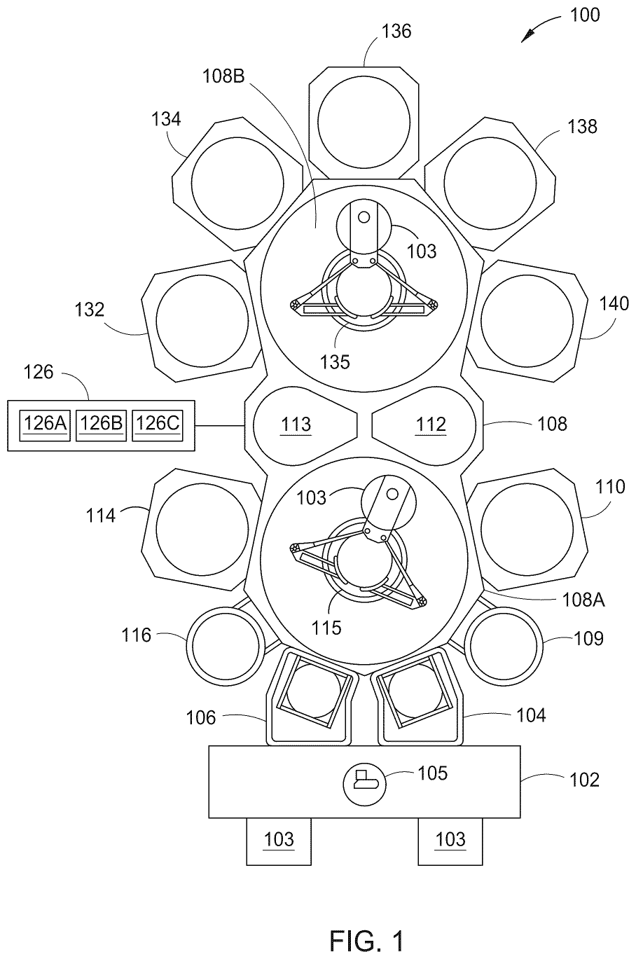

FIG. 1 illustrates a schematic representation of a processing system 100 for use with one or more embodiments described herein. As detailed below, substrates in the processing system 100 may be processed in and transferred between the various chambers without exposing the substrates to an ambient environment exterior to the processing system 100 (for example, an atmospheric ambient environment such as may be present in a fab). For example, the substrates may be processed in and transferred between the various chambers maintained at a low pressure (for example, less than or equal to about 300 Torr) or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

Examples of a processing system that may be suitably modified in accordance with the teachings provided include the Endura®, Producer® or Centura® integrated processing systems or other suitable processing systems commercially available from Applied Materials, Inc., located in Santa Clara, California (CA), United States of America. One may envision that other processing systems, including those from other manufacturers, may be adapted to benefit from aspects described.

FIG. 1 is a schematic top view of the substrate processing system 100 (also referred to as a “processing platform”), according to embodiments described herein. The substrate processing system 100 generally includes an equipment front-end module (EFEM) 102 for loading substrates into the processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the front opening unified pods (FOUPs) 103 to at least one of the first load lock chamber 104 or the second load lock chamber 106. Proceeding counterclockwise around a buffer portion 108A of the transfer chamber 108 from the first load lock chamber 104, the processing system 100 includes a first dedicated degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114, and the pass-through chambers 112, 113.

The back-end portion 108B of the transfer chamber 108 includes a second robot 135 that is configured to transfer substrates to each of the pass-through chambers 112, 113 and the processing chambers coupled to the back-end portion 108B of the processing system 100. The processing chambers can include a first processing chamber 132, a second processing chamber 134, a third processing chamber 136, a fourth processing chamber 138 and a fifth process chamber 140. In general, the processing chambers 132, 134, 136, 138, 140 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138, 140 are a PVD chamber. Examples of PVD chambers suitable for performing the method 300 described herein include the CIRRUS™, AVENIR™ and IMPULSE PVD processing chambers, commercially available from Applied Materials, Inc., of Santa Clara, Calif. In some examples, the processing chamber 110 may be capable of performing an etch process, the processing chamber 114 may be capable of performing a cleaning process or an annealing process, and the processing chambers 132, 134, 136, 138, 140 may be capable of performing respective PVD, CVD or ALD deposition processes. In one example, the processing chambers 132, 134, 136, 138, or 140 may be a Volta™ CVD/ALD chamber, or Encore™ PVD chambers available from Applied Materials of Santa Clara, Calif.

The buffer portion 108A and back-end portion 108B of the transfer chamber 108 and each chamber coupled to the transfer chamber 108 may be maintained at a vacuum state. As used herein, the term “vacuum” may refer to pressures less than 760 Torr, and will typically be maintained at pressures near 10⁻⁵ Torr (that is, ˜10⁻³ Pa). However, some high-vacuum systems may operate below near 10⁻⁷ Torr (that is, ˜10⁻⁵ Pa). In certain embodiments, the vacuum is created using a rough pump and/or a turbomolecular pump coupled to the transfer chamber 108 and to each of the one or more process chambers (for example, process chambers 109-140). However, other types of vacuum pumps are also contemplated.

A system controller 126, such as a programmable computer, is coupled to the processing system 100 for controlling one or more of the components therein. For example, the system controller 126 may control the operation of one or more of the processing chambers, such as processing chambers 132, 134, 136, 138, 140. In operation, the system controller 126 enables data acquisition and feedback from the respective components to coordinate processing in the processing system 100.

The system controller 126 includes a programmable central processing unit (CPU) 126A, which is operable with memory 126B (for example, non-volatile memory) and support circuits 126C. The support circuits 126C (for example, cache, clock circuits, input/output subsystems, power supplies, etc., and combinations thereof) are conventionally coupled to the CPU 126A and coupled to the various components within the processing system 100.

In some embodiments, the CPU 126A is one of any form of general purpose computer processor used in an industrial setting, such as a programmable logic controller (PLC), for controlling various monitoring system component and sub-processors. The memory 126B, coupled to the CPU 126A, is non-transitory and is typically one or more of readily available memory such as random access memory (RAM), read only memory (ROM), floppy disk drive, hard disk, or any other form of digital storage, local or remote.

Herein, the memory 126B is in the form of a computer-readable storage media containing instructions (for example, non-volatile memory), that when executed by the CPU 126A, facilitates the operation of the processing system 100. The instructions in the memory 126B are in the form of a program product such as a program that implements the methods of the present disclosure (for example, middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (for example, read-only memory devices within a computer such as CD-ROM disks readable by a CD-ROM drive, flash memory, ROM chips or any type of solid-state non-volatile semiconductor memory) on which information is permanently stored; and (ii) writable storage media (for example, floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. The various methods disclosed herein may generally be implemented under the control of the CPU 126A by the CPU 126A executing computer instruction code stored in the memory 126B (or in memory of a particular processing chamber) as, for example, a software routine. When the computer instruction code is executed by the CPU 126A, the CPU 126A controls the chambers to perform processes in accordance with the various methods.

As will be described further below, in one or more embodiments of the substrate processing sequence described herein, all of the processes are performed under vacuum within the processing system 100. In one example of the processing system 100, a remote-plasma-source (RPS) cleaning process is performed in chamber 110, a precleaning process is performed in chamber 114, and one or more of a deposition, an etching, and/or a thermal processing process is performed in at least one of the chambers 132, 134, 136, 138, and 140. In one example, the remote plasma (RPS) assisted process performed in chamber 110 is performed in a processing chamber, such as Aktiv™ Preclean (APC) chamber available from Applied Materials of Santa Clara, Calif. In another example, the processing chambers 132, 134, 136, 138, or 140 may be a Volta™ CVD/ALD chamber, or Encore™ PVD chambers available from Applied Materials of Santa Clara, Calif.

In another example of the processing system 100, a remote-plasma-source (RPS) cleaning process and a precleaning process are both performed in at least one of the chambers 110 and 114, and one or more of a deposition, an etching, and/or a thermal processing process is performed in at least one of the chambers 132, 134, 136, 138, and 140.

### Processing Chamber Example

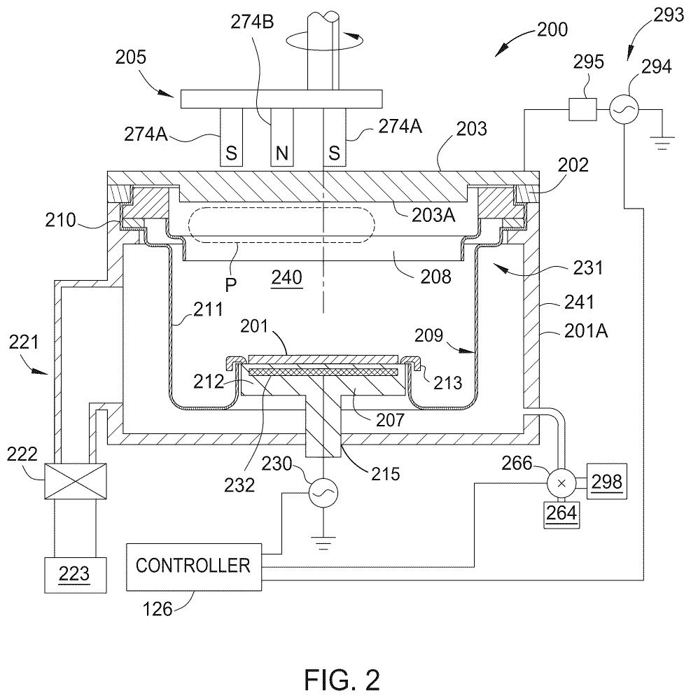

A processing chamber 200, or reactor, that is adapted to deposit a suitable sputtered film on a surface of substrates 201 is illustrated in FIG. 2. One or more of the processing chambers 132, 134, 136, 138, or 140 may contain the components found in the processing chamber 200, which is a magnetron type PVD chamber available from Applied Materials, Inc. of Santa Clara, California.

The processing chamber 200 includes a vacuum chamber 241, a target 203, a magnetron 205, vacuum pumping system 221, a substrate support assembly 207, and a process kit 231. The vacuum chamber 241 supports the target 203, which is sealed at one end of the vacuum chamber 241 through a target isolator 202 using a plurality of o-rings. The target 203 has at least a surface portion composed of material to be sputter deposited on substrate 201. The magnetron 205, which is disposed adjacent to and rotated relative to the target 203, includes a plurality of magnets 274A-274B that are used to confine a plasma generated in the processing region 240 by biasing the target 203 using a power source 293 to “sputter” material from the target surface 203A. It is appreciated that the type of magnetron may vary, depending upon the particular application. The power source 293 generally comprises a power supply 294 that is configured to deliver direct current DC and/or radio frequency (RF) power to the target 203. In some RF power delivery configurations, the power source 293 may also include a match 295.

The vacuum pumping system 221 generally comprises a pump assembly 223 and valve 222. The pump assembly 223 will generally comprise a cryopump (not shown) and roughing pump(s) (not shown) that are used to maintain a desirable pressure in the processing region 240 of the processing chamber 200.

In one embodiment, the substrate support assembly 207 comprises a pedestal electrode 232, which may comprise an electrostatic chuck 212 that has a supporting surface that is adapted to support a substrate 201 over the pedestal electrode 232. Resistive heaters (not shown), refrigerant channels (not shown), and a thermal transfer gas cavities (not shown) may be formed in the substrate support assembly 207 to provide thermal control of the substrates during processing. In some applications, the pedestal electrode 232, which is coupled to a power source 230, may apply an RF and/or a DC bias to the substrates 201 to attract plasma ionized deposition material and process gases. In other applications, biasing of the substrates may be reduced or eliminated to further reduce the potential for damage to the deposited layer.

In one embodiment, a pulsed DC, RF and/or pulsed RF bias signal is applied to the target 203 by the power source 293, which has been found to significantly improve the deposition of a desirable dielectric layer, such as an aluminum nitride layer, as will be discussed further below. To attract the ions generated by the plasma to sputter the target 203, the target 203 is in one embodiment biased by the power source 293 to provide an average power of 1 to 100 kW, such 1 to 60 kW for example, such as about 5 kW to about 40 kW, such as about 5 kW to about 35 kW. In some embodiments, a constant DC or the pulsed DC signals are applied to the target 203. In some embodiments, the pulsed DC signal may include a signal that has a pulsing frequency between about 50 to 200 KHz and a duty cycle between about 1% and 60%. For example, the pulsing frequency can include a pulsing frequency of about 90 KHz to about 110 kHz and a duty cycle of about 5% to about 15%. One skilled in the art will appreciate that the pulsed bias signal applied to a target 203 can provide many beneficial processing advantages, depending upon the particular application. For example, it is believed that the pulsed bias signal can be used to reduce the deposition rate, form a more stable plasma, and increase the peak energy in the plasma for effectively controlling the plasma chemistry to form a desirable film layer. For example, films which are closer to true stoichiometric proportions might be obtained when a pulsed biasing signal is applied to a target 203. Still other possible features include an increase in film quality. Without being bound by theory, film qualities that may be increased can include increases in thermal conductivity due to larger grain sizes, thereby reducing grain boundaries, as well as an increase in overall kappa value. Additionally, and without being bound by theory the film qualities can include a smaller x-ray diffraction (XRD) measurement values (e.g., omega scan values), thereby indicating a better aligned film and reduced lattice defects. Additionally, and without being bound by theory, the film qualities can include reduced leakage current, reduced stress, and reduced wafer bow.

It is appreciated, however, in some applications, a non-pulsed biasing signal, which is a constant DC or an RF power level bias signal, may be applied to bias the target 203 during one or more parts of the deposition process, or even in combination with a pulsed bias signal, depending upon the particular application.

The process kit 231 generally contains a cover ring 213 and a chamber shield 209 that are separated by a dielectric shield isolator 210. The process kit parts may also include a darkspace shield 208. The process kit 231 parts are positioned within the vacuum chamber 241 to protect the chamber wall 201A, which usually comprises a metal that is electrically grounded, from the sputtered material generated in the processing region 240. The shields 208, 209 are typically composed of stainless steel, and their inner sides (e.g., item number 211) may be bead-blasted or otherwise roughened to promote adhesion of the material sputter deposited on them.

In some applications, the substrate may be biased to attract or repel ions generated in the formed plasma as appropriate for that application. For example, a power source 230 may be provided to apply RF power to the pedestal electrode 232 to bias the substrate 201 to attract deposition material ions during the deposition process. In addition, the power source 230 may be configured to apply RF power to the pedestal electrode 232 to couple supplemental energy to the plasma. During the deposition process, the substrate support assembly 207 may be negatively biased by a source to a negative bias voltage. In some configurations, a capacitor tuner, is used with a power source is used to control the floating potential on the substrate 201 during processing.

If the power source 230, used to bias the substrate 201 through the pedestal electrode 232 of the substrate support, is an RF power supply, the supply may operate at a frequency of 13.56 MHZ, for example. Other frequencies are suitable such as 60 MHz, depending upon the particular application. The pedestal 215 may be supplied with an RF power in a range of about 10 watts to about 5 kW, such as about 250 W. The above-mentioned power and voltage levels and frequencies may vary of course, depending upon the particular application. A computer-based controller 126 may be programmed to control the power levels, voltages, currents and frequencies of the various sources in accordance with the particular application.

Referring again to FIG. 2, a gas source 264 supplies a sputtering working gas, such as, for example, a chemically inactive noble gas, such as argon, to the chamber 104 through a mass flow controller assembly 266 that comprise a plurality of mass flow controllers that are configured to provide gases to the processing region of the process chamber. The gas source 264 is also configured to supplies reactive gases, such as, for example, a nitrogen containing gas (e.g., nitrogen (N₂)) and an oxygen containing gas (e.g., oxygen (O₂)), to the chamber 104 through a mass flow controller assembly 266. The working gas can be admitted to the top of the chamber or, as illustrated, at its bottom, either with one or more inlet pipes penetrating apertures through the bottom of the chamber shield 209 or through a gap between the chamber shield 209, the electrostatic chuck 212, and the pedestal 215. During reactive PVD processes a nitrogen gas may be delivered from a source 298 to form a nitride containing layer, such as aluminum nitride, on the substrate 201.

### Substrate Processing Sequences

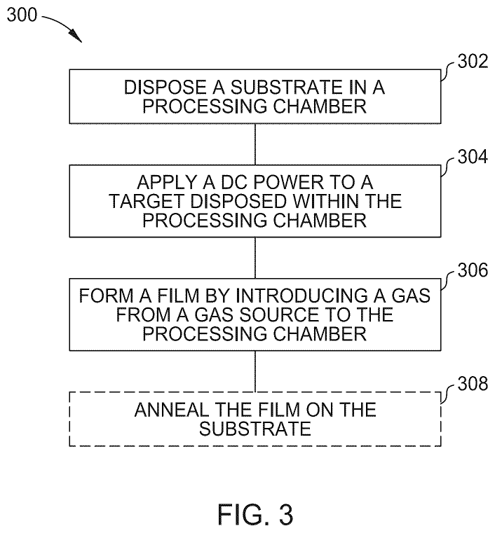

FIG. 3 depicts a process flow diagram of a method 300 of processing a substrate to, for example, form layers useful in backside power delivery network (BSPDN) and Inter-metal dielectric (IMD) applications, according to one or more embodiments of the present disclosure.

At operation 302 a substrate 201 is disposed in a processing chamber 200. The substrate 201 can include any of the substrates as described herein. The processing chamber 200 can include any of the processing chambers as described herein. The substrate 201 can be transferred into the processing chamber 200 using one or more of the robots configured to transfer substrates to each of the pass-through chambers 112,113 and the processing chambers coupled to the back-end portion 108B.

At operation 304, a DC power is applied to a target 203 disposed within the processing chamber 200. The DC power can include a pulsed DC, RF, and/or pulsed RF bias signal that is applied to the target 203. The DC power can be generated by the power source 293. In some embodiments, the DC power can include an average power of about 1 to 100 kW, such 1 to 60 kW for example, such as about 5 kW to about 45 kW, such as about 20 kW to about 42 kW, such as about 30 kW to about 42 kW. In some embodiments, the DC power can include an average power of at least 25 kW, such as at least 30 kW, such as at least 35 kW, or as at least 40 kW, such as between about 30 kW to about 60 kW, such as about 35 kW to about 60 kW. In some embodiments, the DC power can be applied to the target 204 at a pulsing frequency of about 50 to about 200 kHz, and a duty cycle of about 1% to about 60%. For example, the pulsing frequency can include a pulsing frequency of about 90 KHz to about 110 kHz and a duty cycle of about 5% to about 15%. For example, the DC power can include a power of about 35 kW that is pulsed at a frequency of about 100 KHz and a duty cycle of about 10%. Without being bound by theory, an increase in DC power can provide advantageous highly conductive dielectric film, e.g., aluminum nitride (AlN) and/or aluminum oxynitride (AlON), quality improvements such as increased thermal conductivity, increased kappa values, reduced XRD measurement values, reduced leakage currents, reduced stresses, and reduced wafer bows.

At operation 306, a film is formed on the substrate 201. The film can include an AlN film and/or an AlON film. The film can be formed by introducing a process gas from a gas source 264 to the processing chamber 200. The process gas can include a sputtering working gas such as a chemically inactive noble gas (e.g., inert gas), such as argon. The gas can include a reactive gas(es), such as, for example, a nitrogen containing gas (e.g., nitrogen (N₂)) and/or an oxygen containing gas (e.g., oxygen (O₂)). The sputtering working gas and/or the reactive gases can be admitted to the top or side of the chamber or, as illustrated in FIG. 2, at its bottom, either with one or more inlet pipes penetrating apertures through the bottom of the chamber shield 209 or through a gap between the chamber shield 209, the electrostatic chuck 212, and the pedestal 215. The sputtering working gas and/or the reactive gas may be introduced to the processing chamber 200 at a flow rate of about 20 sccm to about 400 sccm, e.g., about 20 sccm to about 380 sccm, about 20 sccm to about 220 sccm, or about 45 sccm to about 120 sccm. In some embodiments, the process gas provided to the processing region of the chamber includes a reactive gas, such as nitrogen and an inert gas, such as argon (Ar). The process gas may include a nitrogen to argon flow rate ratio (i.e., N₂/Ar flow rate ratio) that is greater than 5, such as greater than 10, such as greater than 12, such as greater than 14, or greater than 16 when depositing an AlN containing film. The process gas may also include a nitrogen to oxygen flow rate ratio (i.e., N₂/O₂ flow rate ratio) that is less than 6, such as a ratio between 1 and 6.

The sputtering working gas and/or the reactive gas, e.g., nitrogen and/or oxygen, may be introduced to the processing chamber to form a film including a nitride containing layer, such as AlN and/or ALNO, on the substrate 201. Without being bound by theory, the AlN film disclosed herein can result in a 0.22° K/W decrease in thermal resistance compared to conventional oxide films in conventional BSPDN structures. Additionally, and without being bound by theory, an AlN film including a bonding layer of silicon oxide (SiOx) to enhance adhesion between the substrate 201 and the AlN film can result in a thermal resistance increase of about 0.02° K/W compared to the AlN film, thereby allowing for an advantageous bonding improvement without significantly increasing thermal resistance to that of conventional oxide films used in conventional BSPDN structures.

In some embodiments, during operation 306, the substrate support assembly 207 can be maintained at a temperature of about 250° C. to about 450° C., e.g., about 300° C. to about 450° C. or about 350° C. to about 400° C. In some embodiments, during operation 306, the pressure of the processing chamber 200 can be maintained at a pressure of about 1 mTorr to about 10 mTorr, e.g., about 1 mTorr to about 8 mTorr, about 4 mTorr to about 8 mTorr, or about 5 mTorr to about 7 mTorr. In some embodiments, during operation 306, a plasma heating can be maintained at a temperature of about 0.15 to about 0.45 Ts/Tm, where Ts is the temperature of the substrate and Tm is the melting point temperature of the sputtered material.

In some embodiments, during operation 306, gas, e.g., sputtering working gas and/or reactive gas may be introduced to the processing chamber 200 to provide a deposition rate of about 5 Å/s to about 35 Å/s, e.g., about 10 Å/s to about 35 Å/s, about 20 Å/s to about 35 Å/s, about 25 Å/s to about 35 Å/s, or about 30 Å/s to about 32 Å/s.

The film can include a stress of about 50 MPa to about 600 MPa, e.g., about 100 MPa to about 500 MPa, about 200 MPa to about 400 MPa, or about 340 MPa to about 360 MPa. The film can include a wafer bow of about 150 μm to about 250 μm, e.g., about 150 μm to about 220 μm, about 180 μm to about 220 μm, or about 190 μm to about 210 μm. The film can include a film stress of about-300 MPa to about 300 MPa, e.g., about-200 MPa to about 200 MPa, about-100 MPa to about 100 MPa, or about-50 MPa to about 50 MPa. Optionally, the film stress can be tuned by applying an AC bias applied to an electrode disposed within the substrate support, wherein the AC bias can include a bias of about 1 W to about 250 W, e.g., about 1 W to about 200 W, about 10 W to about 200 W, or about 100 W to about 200 W.

The film can include a Kappa (W/m) of about 63 W/m to about 160 W/m, e.g., about 63 W/m to about 100 W/m, about 70 W/m to about 90 W/m, about 70 W/m to about 83 W/m, or about 70 W/m to about 75 W/m, across a central and/or lateral (edge) position of the substrate 201. The film can include a grain size of about 70 nm to about 85 nm, e.g., about 70 nm to about 83 nm, about 74 nm to about 83 nm, or about 75 nm to about 83 nm, across a central and/or lateral (edge) position of the substrate 201. The film can include a thickness of about 200 nm to about 400 nm, e.g., about 200 nm to about 350 nm, about 250 nm to about 350 nm, or about 280 nm to about 320 nm. The film can include an omega scan (°, XRD) of about 1.36° to about 1.53°, e.g., about 1.364° to about 1.524°, about 1.4° to about 1.5°, or about 1.45° to about 1.49° across a central and/or lateral (edge) position of the substrate 201.

The film can include a leakage current (A/cm²) of about 1.2×10⁻⁸ A/cm² to about 5.6×10⁻⁷ A/cm², e.g., about 1.5×10⁻⁸ A/cm² to about 5.0×10⁻⁷ A/cm², about 2.0×10⁻⁸ A/cm² to about 4.5×10⁻⁷ A/cm², or about 3.0×10⁻⁸ A/cm² to about 4.0×10⁻⁷ A/cm² across a central and/or lateral (edge) position of the substrate 201. The film can include a roughness of about 2.5 nm to about 3.6 nm, e.g., about 2.6 nm to about 3.6 nm, about 2.6 nm to about 3.5 nm, or about 2.8 nm to about 3.2 nm, across a central and/or lateral (edge) position of the substrate 201. The film can include a dielectric current of about 10 to about 12. Without being bound by theory, an increased DC power of about 20 kW to about 42 kW allows for a reduced stress, reduced bow, reduced leakage current, and reduced kappa value compared to conventional oxide films of conventional BSPDN structures.

Optionally, at operation 308, the film is annealed on the substrate 201. The film may be annealed using one or more annealing processes, e.g., baking process. The annealing process can occur in the processing chamber 200 and/or one or more additional and/or alternative chambers, e.g., processing chambers 132, 134, 136, 138, 140. The annealing process can include increasing a temperature of the processing chamber 200 to a temperature (an annealing temperature) of about 400° C. to about 1200° C., e.g., about 600° C. to about 1200° C., about 800° C. to about 1200° C., or about 1000° C. to about 1200° C. The annealing process can include increasing the temperature of the processing chamber 200 to a temperature of about 400° C. to about 1200° C. for a period of about 1 s to about 10 s, e.g., about 1 s to about 8 s, about 1 s to about 6 s, or about 1 s to about 3 s. Without being bound by theory, by annealing the film on the substrate 201, a reduction of the leakage current may occur, thereby reducing the leakage current to below 1×10⁻⁴ A/cm² at 2 MV/cm. Without being bound by theory, by annealing the film on the substrate 201, a reduction of the leakage current may occur, thereby reducing the leakage current to below 1×10⁻⁷ A/cm² at 2 MV/cm. Without being bound by theory, annealing the film on the substrate 201 can include decreasing the leakage current of the film without reducing the dielectric constant of the film.

Optionally, operations 306 and/or 308 can include introducing an oxidizing agent to the film. The oxidizing agent can include a reactive gas, e.g., oxygen. The oxidizing agent can be introduced to the processing chamber at a flow rate of about 10 sccm to about 100 sccm, e.g., about 20 sccm to about 100 sccm, about 30 sccm to about 80 sccm, or about 40 sccm to about 60 sccm. The oxidizing agent can react with the film, e.g., AlN film, to produce an AlON film. Without being bound by theory, by introducing the oxidizing agent to the processing chamber the leakage current may be further reduced from about 3×10⁻⁴ A/cm² at 4 MV/cm to about 4×10⁻⁸ A/cm² at 4 MV/cm. Additionally, and without being bound by theory, the dielectric value of the AlON film and/or Al₂O₃ film may be about 9.0 to about 11, which is an increase from about 8.5 to about 9.1 of the AlN film.

Overall, the present disclosure provides methods for depositing a film on a substrate. The methods include increasing a DC power applied to the target, thereby increasing film qualities, e.g., increased thermal conductivity, reduced grain boundary, increased kappa value, reduced XRD measurement values, reduced lattice defects, reduced leakage current, reduced stress, and reduced wafer bow. The methods can also include introducing an oxidizing agent to further reduce the leakage current of the film.

While the foregoing is directed to embodiments of the present disclosure, other and further embodiments of the disclosure may be devised without departing from the basic scope thereof, and the scope thereof is determined by the claims that follow.

We claim:

1. A method for depositing a layer on a substrate, comprising:
flowing a process gas that comprises a sputtering working gas and a reactive gas to a processing region of a physical vapor deposition chamber, wherein the sputtering working gas comprises an inert gas and the reactive gas comprises nitrogen;
biasing a target disposed in a processing chamber, wherein the biasing of the target comprises providing a direct current (DC) power of at least 30 kilowatts (kW) to the target while the process gas is flowing, wherein the target comprises aluminum (Al); and
heating the substrate disposed within the processing region to a temperature between about 200° C. and about 400° C. while flowing the process gas and biasing the target.

2. The method of claim 1, wherein the inert gas comprises argon (Ar) and the process gas further comprises a nitrogen to argon flow rate ratio of greater than 5.

3. The method of claim 1, wherein the inert gas comprises argon (Ar) and the process gas further comprises a nitrogen to argon flow rate ratio of greater than 14.

4. The method of claim 1, further comprising biasing the substrate, wherein biasing the substrate comprises delivering a radio frequency (RF) power to an electrode disposed within a substrate support on which the substrate is positioned during the process of depositing the layer.

5. The method of claim 1, wherein biasing the target further comprises delivering a pulsed DC signal at a pulsing frequency between about 50 to 200 kHz and a duty cycle between about 1% and 60%.

6. The method of claim 1, further comprising heating the substrate to an annealing temperature, wherein the annealing temperature is greater than about 400° C.

7. A method for depositing a layer on a substrate, comprising:
flowing a process gas that comprises a sputtering working gas and a reactive gas to a processing region of a physical vapor deposition chamber, wherein the sputtering working gas comprises an inert gas and the reactive gas comprises nitrogen and oxygen;
biasing a target disposed in a processing chamber, wherein the biasing of the target comprises providing a DC power of at least 30 kilowatts (kW) to the target while the process gas is flowing, wherein the target comprises aluminum (Al); and
heating the substrate disposed within the processing region to a temperature between about 200° C. and about 400° C. while flowing the process gas and biasing the target.

8. The method of claim 7, wherein the inert gas comprises argon (Ar) and the process gas further comprises a nitrogen to argon flow rate ratio of greater than 5.

9. The method of claim 7, wherein the inert gas comprises argon (Ar) and the process gas further comprises a nitrogen to argon flow rate ratio of greater than 14.

10. The method of claim 7, further comprising biasing the substrate, wherein biasing the substrate comprises delivering a radio frequency (RF) power to an electrode disposed within a substrate support on which the substrate is positioned during the process of depositing the layer.

11. The method of claim 7, wherein biasing the target further comprises delivering a pulsed DC signal at a pulsing frequency between about 50 to 200 KHz and a duty cycle between about 1% and 60%.

12. The method of claim 7, further comprising heating the substrate to an annealing temperature, wherein the annealing temperature is greater than about 400° C.

13. The method of claim 7, wherein the process gas has a nitrogen to oxygen flow rate ratio less than 6.

14. A processing chamber comprising:
a target comprising aluminum (Al);
a system controller; and
a memory for storing a program to be executed in the system controller, the program comprising instructions when executed cause the system controller to execute a method of:
flow a process gas that comprises a sputtering working gas and a reactive gas to a processing region of the processing chamber, wherein the sputtering working gas comprises an inert gas and the reactive gas comprises nitrogen;
bias the target, wherein the biasing of the target comprises providing a direct current (DC) power of at least 30 kilowatts (kW) to the target while the process gas is flowing, wherein the target; and
heat a substrate disposed within the processing region to a temperature between about 200° C. and about 400° C. while flowing the process gas and biasing the target.

15. The processing chamber of claim 14, wherein the inert gas comprises argon (Ar) and the process gas further comprises a nitrogen to argon flow rate ratio of greater than 5.

16. The processing chamber of claim 14, wherein the inert gas comprises argon (Ar) and the process gas further comprises a nitrogen to argon flow rate ratio of greater than 14.

17. The processing chamber of claim 14, wherein the instructions further comprise instructions to bias the substrate, wherein biasing the substrate comprises delivering a radio frequency (RF) power to an electrode disposed within a substrate support on which the substrate is positioned.

18. The processing chamber of claim 14, wherein biasing the target further comprises delivering a pulsed DC signal at a pulsing frequency between about 50 to 200 kHz and a duty cycle between about 1% and 60%.

19. The processing chamber of claim 14, wherein the instructions further comprise instructions to heat the substrate to an annealing temperature, wherein the annealing temperature is greater than about 400° C.

20. The processing chamber of claim 14, wherein the reactive gas further comprises oxygen and the process gas has a nitrogen to oxygen flow rate ratio less than 6.
